(19) United States
(12) Patent Application Publication
(10) Pub. No.: US 2015/0173171 A1
(43) Pub. Date: Jun. 18, 2015

(54) DISPLAY DEVICE

(71) Applicant: SAMSUNG DISPLAY CO., LTD., Yongin-City (KR)

(72) Inventors: Tae-Eun Kim, Yongin-City (KR); Jong-Nam Lee, Yongin-City (KR)

(73) Assignee: SAMSUNG DISPLAY CO., LTD., Yongin-City (KR)

(21) Appl. No.: 14/295,199

(22) Filed: Jun. 3, 2014

(30) Foreign Application Priority Data
Dec. 17, 2013 (KR) 10-2013-0156935

(51) Int. Cl. H05K 1/02

(52) U.S. Cl. CPC H05K 1/028; H05K 1/02; H05K 2201/10128; H05K 2201/09063

(57) ABSTRACT

A display device includes a display panel having a first surface and a second surface opposite the first surface, and a flexible circuit having a first end portion connected to the first surface of the display panel and a second end portion folded around the first end portion of the display panel and coupled the second surface of the display panel. The flexible circuit unit may include at least one slit having a width extending substantially parallel to the first end portion of the display panel and a height extending substantially perpendicular to the width, the height of the slit being greater than the width.

### CROSS-REFERENCE TO RELATED APPLICATION

This application claims priority to and the benefit of Korean Patent Application No. 10-2013-0156935, filed on Dec. 17, 2013, with the Korean Intellectual Property Office, the entire disclosure of which is incorporated herein by reference.

### BACKGROUND

1. Field

Embodiments of the present invention relate to a display device having a flexible circuit unit.

2. Description of the Related Art

Recently, there has been a growing focus on development of a flexible display device in which a display panel of the display device may be bent. This type of flexible display device is configured to be used in a folded or curved shape making it versatile and able to be utilized in many different fields.

This type of flexible display device may include a display element on a flexible substrate. The display element may include, for example, an organic light emitting diode (OLED), a liquid crystal display (LCD), an electrophoretic display (EPD), etc. Among these display elements types, an OLED is very flexible because it may be manufactured to have a thin film laminated structure, and thus the OLED is most often utilized as the display element of these flexible display devices.

In general, OLED displays may include a display panel where an image is displayed, and a flexible circuit unit providing a driving signal to one side of the display panel. The flexible circuit unit may include, for example, a driving printed circuit board (PCB) providing the driving signal to the display panel and a chip on flexible printed circuit or a chip-on-film (COF) to connect the display panel to the driving PCB.

However, in these flexible display devices where during assembly of the display device the COF, made of a flexible material, must be folded toward a rear surface of the display panel so that the driving PCB may be placed on the rear surface of the display panel, a folding stress on the COF may result. Further, the COF of these flexible display devices may be further subjected to stresses when a user of the flexible display device folds or manipulates the flexible display device into a curved state.

In flexible display devices where a folded direction of the COF is different from a curved direction thereof during the assembly process, a folded part of the COF may be subjected to stress at least in each of these directions. Such stress may damage the COF, and the damage to the COF may cause a wiring break that may result in product defects.

Therefore, it is optimal that the stress applied to the flexible circuit unit such as the COF be reduced in flexible display devices.

### SUMMARY

Aspects of embodiments of the present invention are directed to a display device including a flexible circuit. Additional aspects of embodiments of the present invention are directed to a display device including a flexible circuit unit having a slit.

Further, aspects of embodiments of the present invention are directed to a display device in which stress applied to the flexible circuit unit is minimized by optimizing a size and position of the slit of the flexible circuit unit. Other aspects of embodiments of the present invention are directed to a display device including a flexible circuit unit having a slit and a display panel with a driving signal.

According to an embodiment of the present invention, a display device includes a display panel having a first surface, and a second surface opposite the first surface, and a flexible circuit unit having a first end portion connected to the first surface of the display panel and a second end portion folded around the first end portion of the display panel and coupled to the second surface of the display panel, wherein the flexible circuit unit includes at least one slit having a width extending substantially parallel to the first end portion of the display panel and a height extending substantially perpendicular to the width, the height of the slit being greater than the width.

The display panel may have radius of curvature in a direction perpendicular to the first end portion of the display panel.

The flexible circuit unit may include a driving printed circuit board (PCB) configured to provide a driving signal and a chip on flexible printed circuit or chip-on-film (COF) configured to connect the first surface of the display panel to the driving PCB.

The slit may be on the chip on flexible printed circuit (COF).

The chip on flexible printed circuit (COF) may include a driving chip spaced from the slit.

The flexible circuit unit may include at least two slits defined in an area at least on one side of the chip on flexible printed circuit (COF) outside of an area including the driving chip.

In an embodiment, at least one slit may be defined in the area including the driving chip.

The ratio of the width to the height of the slit may range from approximately 1:2 to approximately 1:25.

The width of the slit may range from approximately 0.2 millimeter (mm) to approximately 0.8 mm.

The height of the slit may range from approximately 1 mm to approximately 5 mm.

The display panel may have a radius of curvature ranging from approximately 300 mm to approximately 500 mm.

According to embodiments of the present invention, the slit of the flexible circuit unit may minimize stress applied to the flexible circuit unit of the display device, and, thus, damage caused by the stress occurring when the display device is bent may be reduced. Further, according to embodiments of the present invention, the slit of the flexible circuit unit, which has an optimized size and position, may minimize area loss of a signal input line, thereby allowing the display device to be thinner.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

The above-described and other features and aspects of the present invention will be more clearly understood from the following detailed description, taken in conjunction with the accompanying drawings, in which:

FIG. 1 is an exploded perspective view showing a flexible organic light emitting diode display according to an embodiment of the present invention;

FIG. 2 is a cross-sectional view showing an organic light emitting diode display according to an embodiment of the present invention;

FIG. 3 is a perspective view of an organic light emitting panel provided with a chip on flexible printed circuit (COF) and a driving printed circuit board (PCB);

FIGS. 4A to 4C are plan views of chip on flexible printed circuits (COFs) according to various embodiments of the present invention;

FIG. 5 is a plan view of a chip on flexible printed circuit (COF), illustrating a width and height of a slit, and a distance between two slits on the COF;

FIG. 6A is a graph showing results of stress measurement of a chip on flexible printed circuit (COF) relative to the number of slits on the COF;

FIG. 6B is a graph showing results of stress measurement of a chip on flexible printed circuit (COF) relative to the width of the slits on the COF;

FIG. 6C is a graph showing results of stress measurement of a chip on flexible printed circuit (COF) relative to the height of the slits on the COF;

FIG. 7A is a plan view illustrating a display device in which a chip on flexible printed circuit (COF) is folded toward a rear surface of a flexible display panel;

FIG. 7B is a cross-sectional view taken along line 1 of FIG. 7A; and

FIG. 7C is a cross-sectional view taken along line 2 of FIG. 7A.

### DETAILED DESCRIPTION

Embodiments of the present invention will now be described in detail with reference to the accompanying drawings. The invention may, however, be embodied in many different forms and should not be construed as being limited to the embodiments set forth herein. Rather, these embodiments are provided for thoroughness and completeness of the disclosure, and will fully convey the scope of the invention to those skilled in the art.

In the drawings, certain elements or shapes may be simplified or exaggerated to better illustrate embodiments of the present invention, and other elements present in an actual product or other embodiments may also be omitted. Thus, the drawings are intended to facilitate the understanding of the present invention. Like reference numerals refer to like elements throughout the specification.

In addition, when a layer or element is referred to as being “on” another layer or element, the layer or element may be directly on the other layer or element, or one or more intervening layers or elements may be interposed between.

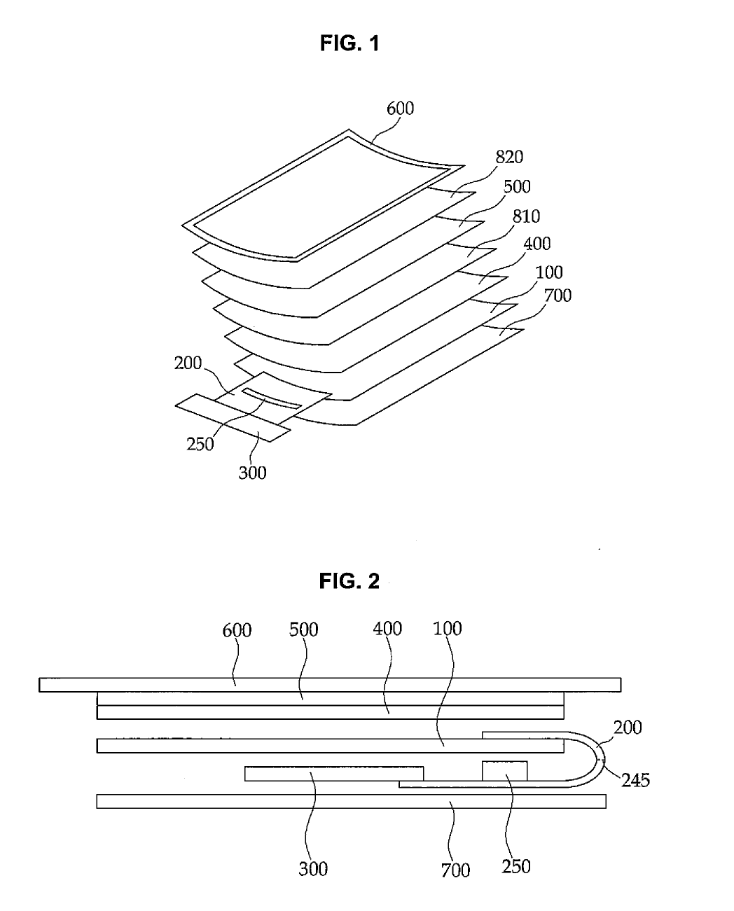

As described herein, according to an embodiment of the present invention, a flexible organic light emitting diode (OLED) display will be described as a display device, with reference to FIG. 1. The term “flexible OLED display” and “display device” may be used interchangeably throughout.

With continued reference to FIG. 1, according to an embodiment of the present invention, the flexible OLED display includes a display panel 100 where an image may be displayed, a polarizer 400 on the display panel 100, a touch panel 500 on the polarizer 400, a window 600 on the touch panel 500, and a buffering member 700 on a rear surface of the display panel 100. Optically clear adhesives (OCAs) 810 and 820, which are adhesive members, may be positioned respectively between the polarizer 400 and the touch panel 500, and between the touch panel 500 and the window 600.

In FIG. 1, a surface toward window 600 where an image may be displayed is referred to as a front surface or a first surface of the display panel 100, and a surface toward buffering member 700 opposite to the first surface of the display panel 100 is referred to as a rear surface or a second surface of the display panel 100.

The polarizer 400, according to an embodiment, may be configured to prevent reflection of external light, while the touch panel 500, according to the embodiment may be configured to input a touch signal of a user, and the window 600 may be configured to protect the display device. Each of these components 400, 500, and 600, according to embodiments of the present invention, may be made of flexible, transparent plastic materials.

The OCAs 810 and 820, which have light transmission characteristics, according to an embodiment, are configured to adhere the polarizer 400 to the touch panel 500, and the touch panel 500 to the window 600.

The buffering member 700, according to an embodiment, is configured to protect the display device from impact.

The display panel 100, according to this embodiment, includes an organic light emitting diode (OLED) as a display element to display an image. The display panel 100 may also be referred to as an organic light emitting panel. The display panel 100, according to an embodiment, may include a substrate and a display unit on the substrate.

The substrate, according to an embodiment, may be made of a flexible plastic material. In this embodiment, the flexible plastic substrate may include, for example, a polyimide (PI) substrate, a polycarbonate (PC) substrate, and a polyacryl (PA) substrate. In an embodiment, the substrate is a PI substrate having optimal optical properties, transparency, durability, and flexibility. According to an embodiment, the display unit on the substrate includes the OLED display element configured to display an image.

According to an embodiment, a plurality of gate lines, a plurality of data lines, and a plurality of power source lines are positioned on the substrate, where individual gate lines and data lines intersect each other to define a pixel. Each pixel, according to other embodiments, may also be defined by a black matrix or a pixel defining layer.

According to an embodiment, a switching thin film transistor (TFT), a driving TFT, a capacitor, and an OLED may be included in each pixel. The switching TFT, according to an embodiment, may be used as a switching element to select a pixel to emit light. The driving TFT, according to an embodiment, applies driving power to a pixel electrode for light emission of an organic light emitting layer of the OLED in a selected pixel. The capacitor, according to an embodiment, may store electric charges corresponding to data voltage, and a current corresponding to the stored electric charges may flow to the OLED through the driving TFT resulting in the OLED emitting light.

The OLED, according to an embodiment, includes a hole injection electrode, the organic light emitting layer, and an electron injection electrode. According to an embodiment, a hole may be injected from the hole injection electrode, and an electron may be injected from the electron injection electrode. The injected hole and electron may be coupled to each other in the organic light emitting layer to form an exciton. According to this embodiment, light is emitted by energy generated when the exciton falls from an excited state to a ground state. In these embodiments, the pixel electrode may be the hole injection electrode or the electron injection electrode.

According to an embodiment, a flexible circuit unit configured to supply driving signals and driving power is located on one side of the display panel 100. The flexible circuit unit may include, for example, a driving printed circuit board (PCB) 300 configured to supply the driving signals, and a chip-on-flexible printed circuit (COF) 200 configured to connect the display panel 100 and the driving PCB 300 together.

FIG. 2 is a cross-sectional view showing an assembled state of components of the OLED display (the OCAs 810 and 820 are not illustrated in FIG. 2).

Referring to the embodiments shown in FIGS. 1 and 2, the display panel 100 has a first surface on which an image is displayed, and a second surface opposite the first surface. The flexible circuit unit is connected to a first end portion of the display panel 100 to supply the driving signals to the first end portion of the display panel 100. A first end portion of the flexible circuit unit, in an embodiment, is connected to the first surface of the first end portion of the display panel 100, and the flexible circuit unit is folded along the first end portion of the display panel 100 so that a second end portion, opposite the first end portion, of the flexible circuit unit is on the second surface of the display panel 100.

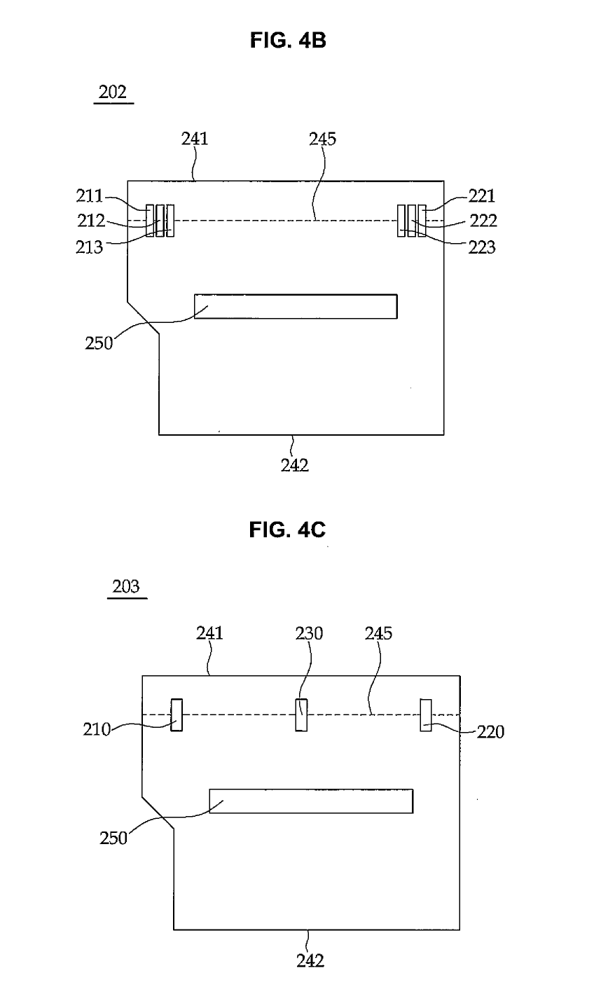

The flexible circuit unit, according to an embodiment, has at least one slit 210, 220, or 230 (shown in FIGS. 4A-4C, for example) having a width w extending substantially parallel to a first end portion of the display panel 100 and a height h extending substantially parallel to a vertical direction of the width w. In an embodiment, a point of the folded part of the flexible circuit unit, which is spaced farthest from the first end portion of the display panel 100, may be defined as a folding line 245, and the slit 210, 220, or 230 may be positioned along the folding line 245 of the flexible circuit unit.

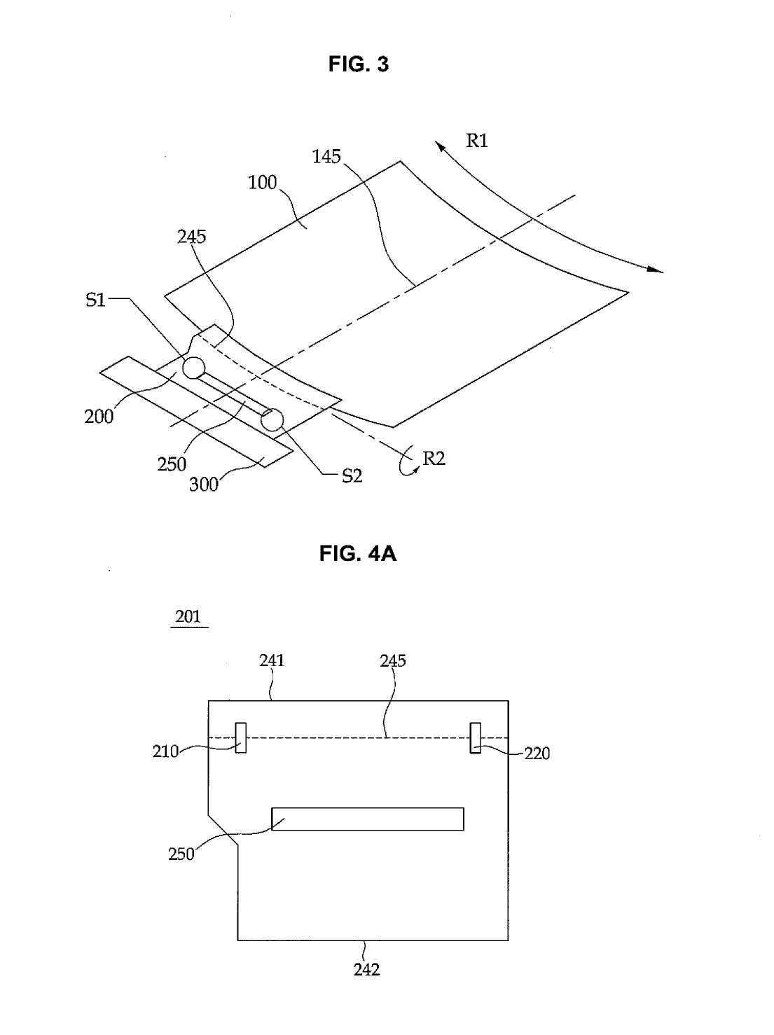

FIG. 3 is a perspective view of an organic light emitting panel provided with the COF and the driving PCB. In the embodiment shown in FIG. 3, the COF 200 and the driving PCB 300 are included in the flexible circuit unit.

The driving PCB 300, according to this embodiment, is configured to supply driving signals, and the COF 200, according to this embodiment, is configured to connect the first surface, which is a display surface of the display panel 100, and the driving PCB 300 together. Thus, according to this embodiment, a first end portion 241 of the COF 200 is connected to the first surface of the first end portion of the display panel 100, and a second end portion 242 of the COF 200, opposite the first end portion 241, is connected to the driving PCB 300.

In this embodiment, the COF 200 may be electrically connected to the display panel 100 through a pad unit of the display panel 100. The pad unit, according to this embodiment, may include a plurality of signal input lines configured to transmit driving power and driving signals input by the driving PCB 300 to the display panel 100, and each signal input line may be connected to components of the display panel 100. Further, according to an embodiment, a driving chip 250 may be connected to least one surface of the COF 200.

The COF 200, in these embodiments, may refer to an element that includes a chip and wire on a base member made of a flexible material such as plastic and that may electrically connect the driving PCB 300 and the display panel 100.

The COF 200, according to an embodiment, is folded along the folding line 245 around the first end portion of the display panel 100, positioning the driving PCB 300 on the second surface of the display panel 100.

The display panel 100 according to the embodiment shown in FIG. 3 is an organic light emitting panel applied to a flexible display device, and having a predetermined radius of curvature. In this embodiment, the display panel 100 is bent along a first bending axis 145 intersecting the folding line 245 at an angle. In an embodiment, the the radius of curvature of the display panel 100 is in a direction perpendicular to the first end portion of the display panel 100. Accordingly, a first bending stress caused by the curvature may be applied to components of the display device, according to this embodiment.

As shown in the embodiment shown in FIG. 3, R1 refers to a bending direction of the display device, and R2 refers to a folding direction of the COF 200 during an assembly process. The COF 200, according to this embodiment, may be folded along the folding line 245 during the assembly process.

The COF 200, according to an embodiment, is folded along the folding line 245 of the display device during assembly, and, thus, the COF 200, according to this embodiment, is subject to folding stresses in addition to first bending stresses. Thus, according to this embodiment, stresses may be applied twice to the COF 200 at an area close to the folding line 245.

The driving chip 250, according to an embodiment, is coupled to or mounted on the COF 200. The driving chip 250, according to these embodiments, treats signals received from the driving PCB 300 and outputs the received signals to the signal input line. However, the driving chip 250, according to these embodiments, is not as flexible as the base member of the COF 200, which, according to an embodiment, may be made of plastic. Stresses that the COF 200 may be subjected to, according to these embodiments, may be applied to areas S1 and S2 of the COF 200 around the driving chip 250.

As described above, various stresses may be applied to the COF 200 structure, and due to these stresses the COF 200 is subjected to, the COF 200 may be damaged such that its wires may become disconnected. Therefore, a reduction of the stresses applied to the COF 200 will prevent or reduce the likelihood of the COF 200 being damaged.

In embodiments where the display panel 100 is subjected to a reduced amount of bending, the first bending stress may be reduced. The first bending stress, according to these embodiments, is inversely proportional to the radius of curvature of the display panel 100, and thus the first bending stress may be reduced by increasing the radius of curvature of the display panel 100. The radius of curvature of the display panel 100, according to these embodiments, is determined by considering a viewing distance (a distance between a user's eyes and a product), and a viewing angle of the user. The radius of curvature of the display panel 100, according to an embodiment of the present invention, ranges from approximately 300 millimeters (mm) to approximately 500 mm.

In order to decrease the stresses applied to the COF 200, the flexible circuit unit of the display device may have a slit 210, 220, or 230 (as shown in FIGS. 4A-4C) according to an embodiment of the present invention.

FIGS. 4A to 4C are plan views of COFs according to embodiments of the present invention.

Referring to the embodiment shown in FIG. 4A, a COF 201 may have first and second slits 210 and 220 on each side (for example, the left and right sides) along the folding line 245 of the COF 201. In this embodiment, a driving chip 250 is separated a distance from the folding line 245.

Referring to the embodiment shown in FIG. 4B, a COF 202 may have at least two slits 211, 212, 213, 221, 222, and 223 on each of the, for example, left and right, sides along the folding line 245 spaced apart from the driving chip 250.

Referring to the embodiment shown in FIG. 4C, a COF 203 may have first, second, and third slits 210, 220, and 230 on, for example, the left and right sides, and in the center, along the folding line 245.

Embodiments of the present invention are not limited to FIGS. 4A to 4C, and the COFs 200, 201, 202, or 203 may have slits 210, 220, 230, 211, 212, 213, 221, 222, and/or 223 having various shapes, and the number of the slits 210, 220, 230, 211, 212, 213, 221, 222, or 223 may be variable.

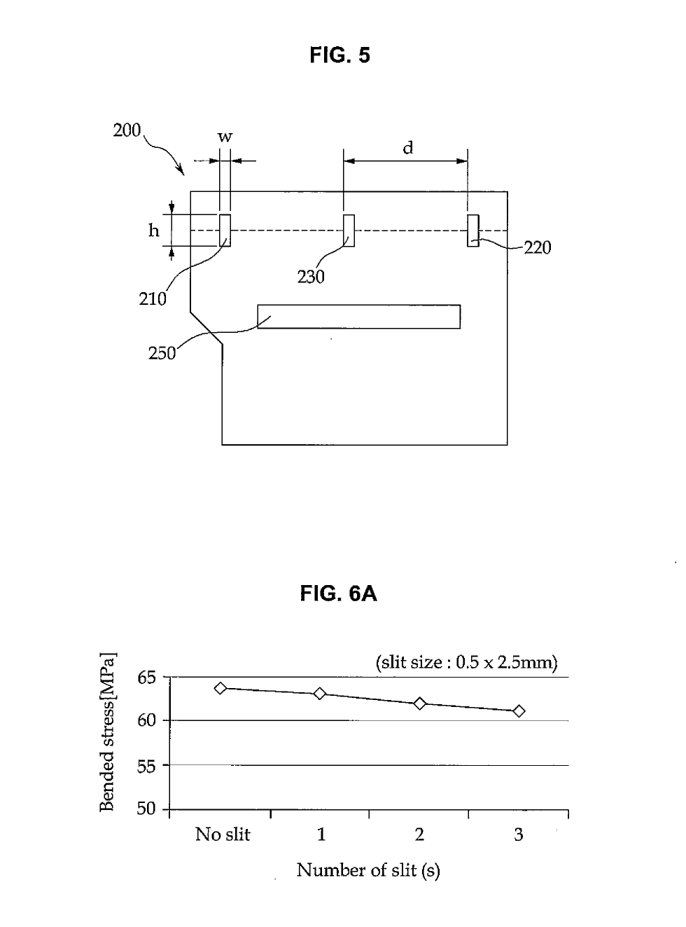

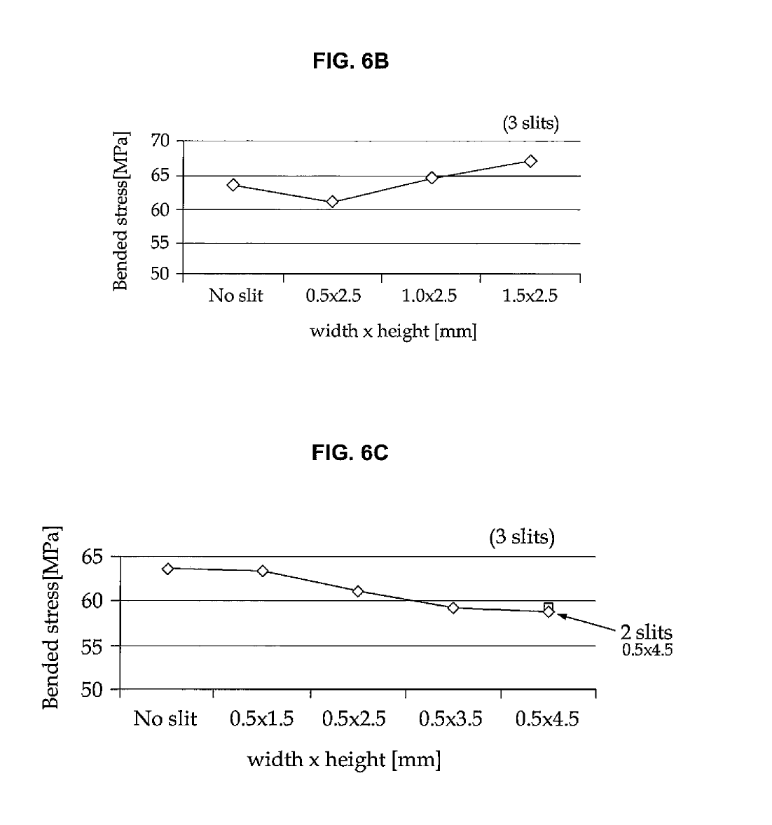

Hereinafter, test results of stress applied to the COF 200 according to shapes and sizes of the slits (for example, 210, 220, 230, 211, 212, 213, 221, 222, and/or 223), as illustrated in FIG. 5, will be described with reference to FIGS. 5 and 6A-6C.

In these embodiments, a stress test was performed using a COF 200 having a size of 43 mm×17 mm and made of a polyimide material. In these embodiments, the folding line 245 is along a long side of the COF 200, the long side having the length of 43 mm, and the COF 200 includes first, second, and third slits 210, 220, and 230 along the folding line 245 (as shown in FIG. 5).

The first, second, and third slits 210, 220, and 230, according to this embodiment, each have a width w extending substantially parallel to the folding line 245 and a height h extending substantially parallel to a vertical direction of the folding line 245, i.e., a vertical direction of the width w. A distance d, according to this embodiment, between the slits 210, 220, and 230 refers to a space between the slits 210, 220, and 230 adjacent to each other. As described herein, being “substantially parallel” may connote deviating at a predetermined angle in addition to being exactly parallel.

The COF 200, according to these embodiments, is bonded to a flexible display panel 100 having a radius of curvature of 315 mm. According to these embodiments, after being bonded to the flexible display panel 100, stress can be measured by folding the COF 200 toward a rear surface of the flexible display panel 100.

FIG. 6A is a graph showing results of stress measurement of the COF relative to the number of the slits. FIG. 6B is a graph showing results of stress measurement of the COF relative to the width of the slits on the COF. FIG. 6C is a graph showing results of stress measurement of the COF relative to the height of the slits on the COF.

Referring to FIG. 6A, the slit (for example 210) has a width w of 0.5 mm and a height h of 2.5 mm, and the distance between the slits (for example between 210 and 220) is 10 mm. As the number of the slits (for example, 210, 220, 230, 211, 212, 213, 221, 222, and/or 223) increases, the stress applied to the COF 200 appears to decrease, as shown in FIG. 6A.

Referring to FIG. 6B, the COF 200 includes three slits (for example, 210, 220, and 230) and each of the slits 210, 220, and 230 has a height h of 2.5 mm. In this example, the slits 210, 220, and 230 have different widths w. As indicated in the graph shown in FIG. 6B, the stress is lowest when the width w of the slit 210, 220, or 230 is 0.5 mm, and the stress occurring in the embodiments where the width w of the slit 210, 220, or 230 is more than 1 mm is greater than the stress occurring in the embodiments where no slit 210, 220, or 230 is provided. Therefore, according to these results, the slits 210, 220, and 230, in an embodiment, have a width w ranging from 0.2 mm to 0.8 mm.

Referring to FIG. 6C, the COF 200 includes three slits (for example, 210, 220, and 230) and each slit (for example, 210, 220, and 230) has a width w of 0.5 mm. In this example, the stress applied to the COF 200 is measured by changing the height h of the slits 210, 220, and 230. As the height h of the slits 210, 220, and 230 increases, the stress appears decrease. In FIG. 6C, the annotated square symbol on the graph indicates the stress applied to a COF 200 having two slits (for example, 210 and 220) each having a width w of 0.5 mm and a height h of 4.5 mm. In the embodiments where the COF 200 includes only two slits 210 and 220, the stress appears to be significantly reduced.

Further, as shown in the examples of FIGS. 6A-6C, reduction of the stress applied to the COF 200 including the slit (for example, 210, 220, or 230) having a height h of 4.5 mm is not greater than that of the stress applied to the COF 200 including the slit (for example, 210, 220, or 230) having a height h of 3.5 mm.

In consideration of the size of the COF 200 coupled to the display device, the slits 210, 220, or 230, according to an embodiment, preferably have a height h ranging from of 1 mm to 5 mm.

Further, as indicated in FIGS. 6A-6C, a larger reduction of stress may be achieved when the height h of each slit 210, 220, or 230 is greater than the width w thereof.

Thus, in an embodiment, stress reduction can be achieved where the COF 200 has slits 210, 220, or 230 having a width w extending substantially parallel to a first end portion of the display panel 100 and a height h extending substantially parallel to a vertical direction of the width w, where the height h of each slit 210, 220, and 230 is greater than the width w.

When considering the width w and height h of the slits (for example 210, 220, and 230) according to the test results, the height h of the slits 210, 220, and 230, according to an embodiment, may range from 2 times to 25 times the width w of the respective slit 210, 220, or 230. Thus, in this embodiment, the ratio of width w to height h of each slit 210, 220, or 230 may range from 1:2 to 25. In one embodiment where the height h of a slit 210, 220, or 230 is less than twice its width w, no significant reduction in stress reduction is achieved. Further, in some embodiments, in consideration of slit fabrication and the size of the flexible circuit unit or the COF 200 coupled to the display device, the height h of the slit 210, 220, or 230 may be 25 times or less its width w. However, in these embodiments, the ratio of width w to height h of the slit 210, 220, or 230 is not limited thereto.

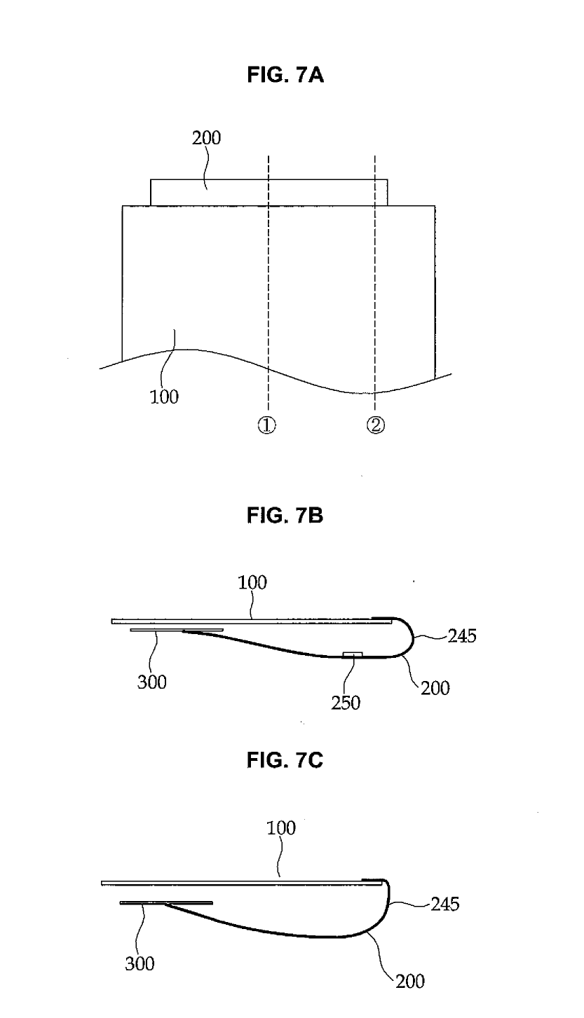

FIG. 7A is a plan view illustrating the display device in which the COF is folded toward the rear surface of the flexible display panel.

FIG. 7B is a cross-sectional view taken along line 1 of FIG. 7A. FIG. 7C is a cross-sectional view taken along line 2 of FIG. 7A.

Referring to the embodiment shown in FIG. 7A, the display panel 100 may have a radius of curvature of approximately 315 mm, and the COF 200 may have a radius of curvature ranging from approximately 0.5 mm to approximately 10 mm in the folding part, and may be bonded to the display panel 100.

Referring to the embodiments shown in FIGS. 7B and 7C, the COF 200 may be separated further down from the display panel 100 in an exterior part (indicated by line 2) of the display panel 100 than in a core part (indicated by line 1) thereof. According to this embodiment, as the COF 200 is spaced farther apart from the display panel 100, a restoring force applied to the COF 200 increases, and the stress applied to the COF 200 also increases. Accordingly, in this embodiment, the stress applied to the COF 200 increases from the center portion of the display panel 100 to the side thereof, and thus the COF 200, according to this embodiment, is positioned on the center portion of the display panel 100.

From the foregoing, it will be appreciated that various embodiments of the present disclosure have been described herein for purposes of illustration, and that various modifications may be made without departing from the scope and spirit of the invention. Accordingly, the various embodiments disclosed herein are not intended to be limiting, with the true scope and spirit being indicated by the following claims, and equivalents thereof.

What is claimed is:

1. A display device comprising:
a display panel having a first surface and a second surface opposite the first surface; and
a flexible circuit unit having a first end portion connected to the first surface of the display panel and a second end portion folded around the first end portion of the display panel and coupled to the second surface of the display panel,
wherein the flexible circuit unit includes at least one slit having a width extending substantially parallel to the first end portion of the display panel and a height extending substantially perpendicular to the width, the height of the slit being greater than the width.

2. The display device of claim 1, wherein the display panel has radius of curvature in a direction perpendicular to the first end portion of the display panel.

3. The display device of claim 1, wherein the flexible circuit unit comprises a driving printed circuit board configured to provide a driving signal; and a chip on flexible printed circuit configured to connect the first surface of the display panel to the driving PCB.

4. The display device of claim 3, wherein the slit is on the chip on flexible printed circuit.

5. The display device of claim 3, wherein the chip on flexible printed circuit comprises a driving chip spaced from the slit.

6. The display device of claim 5, wherein the flexible circuit unit includes at least two slits defined in an area at least on one side of the chip on flexible printed circuit outside of an area including the driving chip.

7. The display device of claim 6, wherein at least one slit is defined in the area including the driving chip.

8. The display device of claim 1, wherein the ratio of the width to the height of the slit ranges from approximately 1:2 to approximately 1:25.

9. The display device of claim 1, wherein the width of the slit ranges from approximately 0.2 millimeter to approximately 0.8 millimeter.

10. The display device of claim 1, wherein the height of the slit ranges from approximately 1 millimeter to approximately 5 millimeters.

11. The display device of claim 2, wherein the display panel has a radius of curvature ranging from approximately 300 millimeters to approximately 500 millimeters.
